(19) United States
(12) Patent Application Publication
(10) Pub. No.: US 2024/0194476 A1
(43) Pub. Date: Jun. 13, 2024

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventors: Yasutoshi TSUBOTA, Toyama-shi (JP); Katsunori FUNAKI, Toyama-shi (JP); Tatsushi UEDA, Toyama-shi (JP); Yuichiro TAKESHIMA, Toyama-shi (JP); Keita ICHIMURA, Toyama-shi (JP); Hiroto IGAWA, Toyama-shi (JP); Yuki YAMAKADO, Toyama-shi (JP); Hiroki KISHIMOTO, Toyama-shi (JP)

(73) Assignee: Kokusai Electric Corporation, Tokyo (JP)

(21) Appl. No.: 18/583,444

(22) Filed: Feb. 21, 2024

Related U.S. Application Data
(63) Continuation of application No. PCT/JP2021/035835, filed on Sep. 29, 2021.

(51) Int. Cl. H01L 21/02

(52) U.S. Cl. CPC H01L 21/02164; H01L 21/02236; H01L 21/02247

(57) ABSTRACT

There is provided a technique that includes: (a) nitriding an inner surface of a recessed structure formed on a substrate to modify at least a portion of the inner surface into a nitride layer; and (b) oxidizing the inner surface including the nitride layer to modify the inner surface into an oxide layer. (a) includes setting a thickness distribution of the nitride layer in the inner surface such that, in (b), a thickness distribution of the oxide layer in the inner surface becomes a desired distribution.

### CROSS-REFERENCE TO RELATED APPLICATION

This application is a Bypass Continuation Application of PCT International Application No. PCT/JP2021/035835, filed on Sep. 29, 2021, the entire contents of which are incorporated herein by reference.

### TECHNICAL FIELD

The present disclosure relates to a method of manufacturing a semiconductor device, a substrate processing method, a substrate processing apparatus, and a program.

### BACKGROUND

As one of processes of manufacturing a semiconductor device, a process of forming an oxide layer in the inner surface of a recessed structure formed on a substrate is sometimes performed.

### SUMMARY

Some embodiments of the present disclosure provide a technique capable of allowing the thickness of an oxide layer formed in the inner surface of a recessed structure formed on a substrate to have a desired thickness distribution.

According to one embodiment of the present disclosure, there is provided a technique, including: (a) nitriding an inner surface of a recessed structure formed on a substrate to modify at least a portion of the inner surface into a nitride layer; and (b) oxidizing the inner surface including the nitride layer to modify the inner surface into an oxide layer, wherein (a) includes setting a thickness distribution of the nitride layer in the inner surface such that, in (b), a thickness distribution of the oxide layer in the inner surface becomes a desired distribution.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a substrate processing apparatus suitably used in one embodiment of the present disclosure, in which the portion of a process furnace is shown in a vertical sectional view.

FIG. 2 is an explanatory diagram illustrating the principle of plasma generation in the substrate processing apparatus suitably used in one embodiment of the present disclosure.

FIG. 3 is a schematic configuration diagram of a controller included in the substrate processing apparatus suitably used in one embodiment of the present disclosure, in which the control system of the controller is shown in a block diagram.

FIG. 4A is a partially enlarged sectional view of a wafer in which a trench is provided.

FIG. 4B is a partially enlarged sectional view of the wafer after at least a portion of the inner surface of the trench has been modified into a nitride layer.

FIG. 4C is a partially enlarged sectional view of the wafer in the process of modifying the inner surface of the trench including the nitride layer into an oxide layer.

FIG. 4D is a partially enlarged sectional view of the wafer after the inner surface of the trench including the nitride layer has been modified into an oxide layer.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### One Embodiment of the Present Disclosure

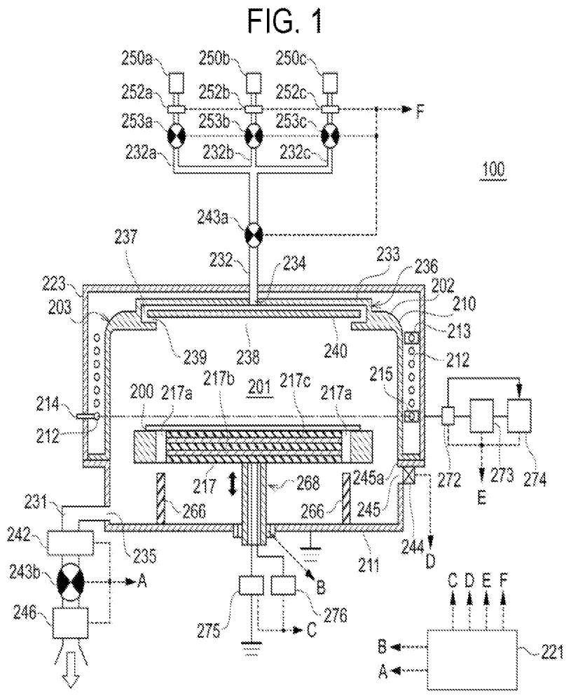

One embodiment of the present disclosure will be described below mainly with reference to FIGS. 1 to 3 and 4A to 4D. The drawings used in the following description are all schematic. The dimensional relationship of each element, the ratio of each element, and the like shown in the drawings do not necessarily match the real ones. Moreover, the dimensional relationship of each element, the ratio of each element, and the like do not necessarily match between a plurality of drawings.

### (1) Configuration of Substrate Processing Apparatus

As shown in FIG. 1, the substrate processing apparatus 100 includes a process furnace 202 that accommodates a wafer 200 as a substrate and performs plasma processing. The process furnace 202 includes a process container 203 that constitutes a process chamber 201. The process container 203 includes a dome-shaped upper container 210 which is a first container, and a bowl-shaped lower container 211 which is a second container. The process chamber 201 is formed by placing the upper container 210 over the lower container 211. The upper container 210 is made of a non-metallic material such as aluminum oxide (Al₂O₃) or quartz (SiO₂), and the lower container 211 is made of aluminum (Al), for example.

A gate valve 244 as a loading/unloading port (partition valve) is provided on the lower side wall of the lower container 211. By opening the gate valve 244, the wafer 200 can be loaded and unloaded into and out of the process chamber 201 via a loading/unloading port 245. By closing the gate valve 244, the airtightness within the process chamber 201 can be maintained.

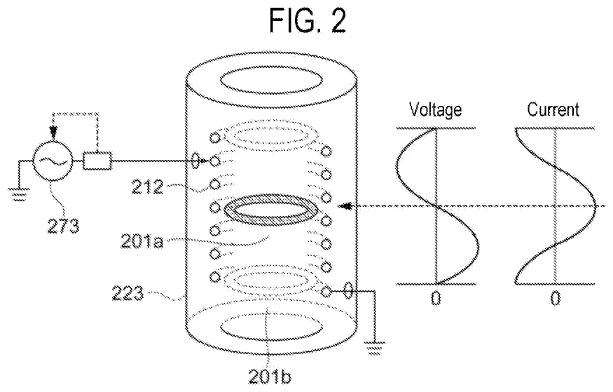

As shown in FIG. 2, the process chamber 201 includes a plasma generation space 201a, and a substrate processing space 201b communicating with the plasma generation space 201a and configured to process the wafer 200 therein. The plasma generation space 201a is a space where plasma is generated, and is a space in the process chamber 201, for example, above the lower end (indicated by a one-dot chain line in FIG. 1) of a resonance coil 212. On the other hand, the substrate processing space 201b is a space where a substrate is processed with plasma, and is a space below the lower end of the resonance coil 212.

At the bottom side center of the process chamber 201, there is arranged a susceptor 217 serving as a substrate mounting part on which the wafer 200 is mounted. The susceptor 217 is made of a non-metallic material such as aluminum nitride (AlN), ceramics, or quartz.

A heater 217b serving as a heating mechanism is integrally embedded inside the susceptor 217. By supplying electric power to the heater 217b via a heater power adjustment mechanism 276, the surface of the wafer 200 can be heated to a predetermined temperature within the range of, for example, 25 degrees C. to 1000 degrees C.

The susceptor 217 is electrically insulated from the lower container 211. An impedance adjustment electrode 217c is provided inside the susceptor 217. The impedance adjustment electrode 217c is grounded via an impedance changing mechanism 275 serving as an impedance adjustment pressure. The impedance changing mechanism 275 includes a coil, a variable capacitor, and the like, and is configured so that, by controlling the inductance and resistance of the coil, the capacitance value of the variable capacitor, and the like, the impedance of the impedance adjustment electrode 217c can be changed within a range from approximately 0Ω to a parasitic impedance value of the process chamber 201. This makes it possible to control the potential (bias voltage) of the wafer 200 during plasma processing via the impedance adjustment electrode 217c and the susceptor 217.

A susceptor elevating mechanism 268 for raising and lowering the susceptor is provided below the susceptor 217. The susceptor 217 is provided with through holes 217a. Support pins 266 serving as support bodies for supporting the wafer 200 is provided on the bottom surface of the lower container 211. The through holes 217a and the support pins 266 are provided in at least three positions facing each other. When the susceptor 217 is lowered by the susceptor elevating mechanism 268, the support pins 266 pass through the through holes 217a without contacting the susceptor 217. This makes it possible to hold the wafer 200 from below.

A gas supply head 236 is provided above the process chamber 201, i.e., in the upper portion of the upper container 210. The gas supply head 236 includes a cap-shaped lid 233, a gas introduction port 234, a buffer chamber 237, an opening 238, a shielding plate 240, and a gas discharge port 239. The gas supply head 236 is configured to supply a gas into the process chamber 201. The buffer chamber 237 functions as a dispersion space for dispersing a reaction gas introduced from the gas introduction port 234.

The downstream end of a gas supply pipe 232a that supplies a nitrogen-containing gas, the downstream end of a gas supply pipe 232b that supplies an oxygen-containing gas, and the downstream end of a gas supply pipe 232c that supplies an inert gas are connected to the gas introduction port 234 to merge with each other. In the gas supply pipe 232a, a nitrogen-containing gas supply source 250a, a mass flow controller (MFC) 252a as a flow rate control device, and a valve 253a as an opening/closing valve are installed sequentially from the upstream side. In the gas supply pipe 232b, an oxygen-containing gas supply source 250b, an MFC 252b as a flow rate control device, and a valve 253b as an opening/closing valve are installed sequentially from the upstream side. In the gas supply pipe 232c, an inert gas supply source 250c, an MFC 252c as a flow rate control device, and a valve 253c as an opening/closing valve are installed sequentially from the upstream side. A valve 243a is installed on the downstream side of the merging point of the gas supply pipe 232a, the gas supply pipe 232b, and the gas supply pipe 232c, and is connected to the upstream end of the gas introduction port 234. By opening and closing the valves 253a to 253c and 243a, a nitrogen-containing gas, an oxygen-containing gas and an inert gas can be supplied into the process chamber 201 through the gas supply pipes 232a, 232b and 232c, respectively, while adjusting the flow rates of the respective gases with the MFCs 252a to 252c, respectively.

A nitrogen-containing gas supply system mainly includes the gas supply head 236 (the lid 233, the gas introduction port 234, the buffer chamber 237, the opening 238, the shielding plate 240, and the gas discharge port 239), the gas supply pipe 232a, the MFC 252a, and the valves 253a and 243a. Further, an oxygen-containing gas supply system mainly includes the gas supply head 236, the gas supply pipe 232b, the MFC 252b, and the valves 253b and 243a. In addition, an inert gas supply system mainly includes the gas supply head 236, the gas supply pipe 232c, the MFC 252c, and the valves 253c and 243a.

An exhaust port 235 for evacuating the inside of the process chamber 201 is provided in the side wall of the lower container 211. The upstream end of an exhaust pipe 231 is connected to the exhaust port 235. In the exhaust pipe 231, an APC (Auto Pressure Controller) valve 242 as a pressure regulator (pressure regulation part), a valve 243b, and a vacuum pump 246 as an evacuation device are installed sequentially from the upstream side.

An exhaust part mainly includes the exhaust port 235, the exhaust pipe 231, the APC valve 242, and the valve 243b. The vacuum pump 246 may be included in the exhaust part.

A spiral resonance coil 212 is installed on the outer periphery of the process chamber 201, i.e., on the outside of the side wall of the upper container 210, to surround the process chamber 201. An RF (Radio Frequency) sensor 272, a high frequency power source 273, and a frequency matcher 274 (frequency control part) are connected to the resonance coil 212. A shielding plate 223 is installed on the outer peripheral side of the resonance coil 212.

The high-frequency power source 273 is configured to supply high-frequency power to the resonance coil 212. The RF sensor 272 is installed on the output side of the high-frequency power source 273. The RF sensor 272 is configured to monitor information about traveling waves and reflected waves of the high-frequency power supplied from the high-frequency power source 273. The frequency matcher 274 is configured to match the frequency of the high-frequency power outputted from the high-frequency power source 273 based on the information on the reflected wave power monitored by the RF sensor 272 so that the reflected waves are minimized.

Both ends of the resonance coil 212 are electrically grounded. One end of the resonance coil 212 is grounded via a movable tap 213. The other end of the resonance coil 212 is grounded via a fixed ground 214. A movable tap 215 capable of arbitrarily setting a position where electric power is supplied from the high-frequency power source 273 is installed between both ends of the resonance coil 212.

An excitation part (plasma generation part) that excites each of the gases supplied from the nitrogen-containing gas supply system and the oxygen-containing gas supply system mainly includes the resonance coil 212, the RF sensor 272, and the frequency matcher 274. The high-frequency power source 273 and the shielding plate 223 may be included in the excitation part.

The operation of the excitation part and the properties of the generated plasma will be described below with reference to FIG. 2.

The resonance coil 212 is configured to function as an inductively coupled plasma (ICP) electrode. The resonance coil 212 generates standing waves having a predetermined wavelength. The winding diameter, winding pitch, number of turns, and the like of the resonance coil 212 are set so that the resonance coil 212 resonates in a full wavelength mode. The electrical length of the resonance coil 212, i.e., the electrode length between the earths is adjusted to be an integral multiple of the wavelength of the high-frequency power supplied from the high-frequency power source 273. These configurations, the electric power supplied to the resonance coil 212, the strength of the magnetic field generated by the resonance coil 212, and the like are appropriately determined in consideration of the external shape of the substrate processing apparatus 100, the process content, and the like. As an example, the coil diameter of the resonance coil 212 is 200 to 500 mm, and the number of turns of the coil is 2 to 60.

The high-frequency power source 273 includes a power source control means and an amplifier. The power source control means is configured to output a predetermined high-frequency signal (control signal) to the amplifier based on the output conditions regarding the electric power and the frequency set in advance through an operation panel. The amplifier is configured to output the high-frequency power obtained by amplifying the control signal received from the power source control means to the resonance coil 212 via a transmission line.

The frequency matcher 274 receives a voltage signal regarding the reflected wave power from the RF sensor 272, and performs correction control to increase or decrease the frequency (oscillation frequency) of the high-frequency power outputted by the high-frequency power source 273 so that the reflected wave power is minimized.

According to the above configuration, the induced plasma excited in the plasma generation space 201a is of good quality having almost no capacitive coupling with the inner wall of the process chamber 201, the susceptor 217, and the like. In the plasma generation space 201a, plasma having an extremely low electric potential and having a donut shape in a plan view is generated.

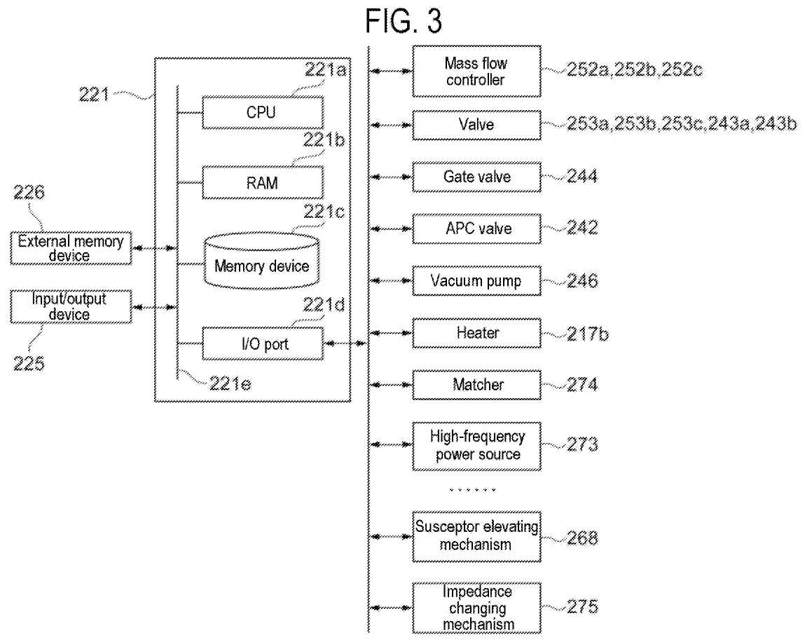

As shown in FIG. 3, the controller 221 as a control part is configured as a computer including a CPU (Central Processing Unit) 221a, a RAM (Random Access Memory) 221b, a memory device 221c, and an I/O port 221d. The RAM 221b, the memory device 221c, and the I/O port 221d are configured to be able to exchange data with the CPU 221a via an internal bus 221e. The controller 221 may be connected to an input/output device 225 such as a touch panel, a mouse, a keyboard, an operating terminal, or the like. For example, a display or the like may be connected to the controller 221 as a display part.

The memory device 221c is formed of, for example, a flash memory, an HDD (Hard Disk Drive), a CD-ROM, and the like. The memory device 221c readably stores a control program for controlling the operation of the substrate processing apparatus 100, a process recipe in which procedures and conditions for a substrate processing process are written, and the like. The process recipe is a combination of instructions that causes the controller 221 configured as a computer to have the substrate processing apparatus 100 execute each procedure in a substrate processing process described below to obtain a predetermined result. The process recipe functions as a program. Hereinafter, the process recipe, the control program, and the like will be collectively and simply referred to as a program. When the word program is used in this specification, it may include only a process recipe, only a control program, or both. The RAM 221b is configured as a memory area (work area) in which programs, data, and the like read by the CPU 221a are temporarily held.

The I/O port 221d is connected to the MFCs 252a to 252c, the valves 253a to 253c, 243a and 243b, the gate valve 244, the APC valve 242, the vacuum pump 246, the heater 217b, the RF sensor 272, the high-frequency power source 273, the frequency matcher 274, the susceptor elevating mechanism 268, the impedance changing mechanism 275, and the like.

The CPU 221a is configured to read a control program from the memory device 221c and execute the control program, and is configured to read a process recipe from the memory device 221c in response to the input of an operation command from the input/output device 225. Then, as shown in FIG. 1, the CPU 221a is configured to control, in accordance with the content of the process recipe thus read, the opening degree adjustment operation of the APC valve 242, the opening/closing operation of the valve 243b, and the start/stop of the vacuum pump 246 are controlled through the I/O port 221d and a signal line A, the elevating operation of the susceptor elevating mechanism 268 through a signal line B, the power amount adjustment operation of the electric power supplied to the heater 217b (the temperature adjustment operation) by the heater power adjustment mechanism 276 based on the temperature sensor and the impedance value adjustment operation by the impedance changing mechanism 275 through a signal line C, the opening/closing operation of the gate valve 244 through a signal line D, the operations of the RF sensor 272, the frequency matcher 274 and the high-frequency power source 273 through a signal line E, and the flow rate adjustment operation for various gases by the MFCs 252a to 252c and the opening/closing operation of the valves 253a to 253c and 243a through a signal line F.

The controller 221 is not limited to being configured as a dedicated computer, but may be configured as a general-purpose computer. For example, the controller 221 according to the present embodiment may be configured by preparing an external memory device (e.g., a magnetic tape, a magnetic disk such as a flexible disk or a hard disk, an optical disk such as a CD or a DVD, a magneto-optical disk such as an MO or the like, or a semiconductor memory such as a USB memory or a memory card) 226 that stores the above-described programs, and installing the programs on a general-purpose computer through the use of the external memory device 226. The means for supplying the programs to the computer is not limited to supplying the programs via the external memory device 226. For example, the programs may be supplied using a communication means such as the Internet or a dedicated line without going through the external memory device 226. The memory device 221c and the external memory device 226 are configured as computer-readable recording media. Hereinafter, these will be collectively and simply referred to as a recording medium. When the term “recording medium” is used in this specification, it may include only the memory device 221c, only the external memory device 226, or both.

### (2) Substrate Processing Process

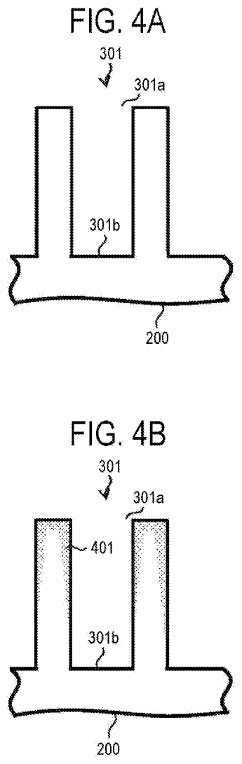

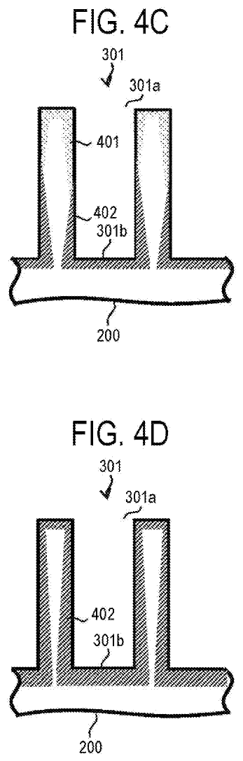

An example of a substrate processing sequence in which the above-described substrate processing apparatus 100 is used to process the wafer 200 as a substrate as one of processes of manufacturing a semiconductor device, specifically, an example of a sequence for forming an oxide layer in the inner surface of a recessed structure formed on the surface of the wafer 200, will be described mainly with reference to FIGS. 4A, 4B, 4C and 4D. In the following description, the operation of each part constituting the substrate processing apparatus 100 is controlled by the controller 221.

In the substrate processing sequence according to the present embodiment, there is performed:
step a of nitriding an inner surface of a recessed structure formed on a wafer 200 to modify at least a portion of the inner surface into a nitride layer; and
step b of oxidizing the inner surface including the nitride layer to modify the inner surface into an oxide layer.

In step a, the thickness distribution of the nitride layer in the inner surface is set such that the thickness distribution of the oxide layer in the inner surface, i.e., the oxide layer formed by performing step b, has a desired thickness distribution.

The term “wafer” used herein may refer to a wafer itself or a stacked body of a wafer and a predetermined layer or film formed on the surface of the wafer. The phrase “a surface of a wafer” used herein may refer to a surface of a wafer itself or a surface of a predetermined layer or the like formed on a wafer. The expression “a predetermined layer is formed on a wafer” used herein may mean that a predetermined layer is directly formed on a surface of a wafer itself or that a predetermined layer is formed on a layer or the like formed on a wafer. The term “substrate” used herein may be synonymous with the term “wafer.”

### (Wafer Loading)

With the susceptor 217 lowered to a predetermined transfer position, the gate valve 244 is opened, and the wafer 200 to be processed is transferred into the process chamber 201 by a transfer robot (not shown). The wafer 200 loaded into the process chamber 201 is supported in a horizontal position on the support pins 266 protruding from the surface of the susceptor 217. After the loading of the wafer 200 into the process chamber 201 is completed, the arm portion of the transfer robot is removed from the process chamber 201, and the gate valve 244 is closed. Thereafter, the susceptor 217 is raised to a predetermined processing position, and the wafer 200 to be processed is delivered from the support pins 266 onto the susceptor 217. The wafer may be loaded while purging the inside of the process chamber 201 with an inert gas or the like.

As described above, a recessed structure such as a trench or a hole is formed in advance on the surface of the wafer 200 to be processed. In the present embodiment, an example will be described in which as shown in FIG. 4A, a trench 301 is formed in advance as a recessed structure on the surface of a wafer 200. It is assumed that the inner surface of the trench 301 according to the present embodiment is formed of, for example, a Si layer made of Si (monocrystalline Si, polycrystalline Si, or amorphous silicon) alone.

### (Pressure Regulation and Temperature Adjustment)

Subsequently, the inside of the process chamber 201 is evacuated by the vacuum pump 246 so that a desired processing pressure is achieved. The pressure inside the process chamber 201 is measured by a pressure sensor, and the APC valve 242 is feedback-controlled based on the measured pressure information. Further, the wafer 200 is heated by the heater 217b so that the wafer 200 has a desired processing temperature. When the pressure inside the process chamber 201 reaches a desired processing pressure and the temperature of the wafer 200 reaches the desired processing temperature and stabilizes at the desired processing temperature, a nitriding process, which will be described later, is started. The vacuum pump 246 is kept operating until wafer unloading, which will be described later, is completed.

Thereafter, the next steps a and b are executed sequentially.

### [Step a: Nitriding Process]

In step a, a nitrogen-containing gas is excited by plasma and supplied to the wafer 200 in the process chamber 201.

Specifically, the valve 253a is opened to allow a nitrogen-containing gas into the gas supply pipe 232a. The flow rate of the nitrogen-containing gas is adjusted by the MFC 252a. The nitrogen-containing gas is supplied into the process chamber 201 via the buffer chamber 237, and is exhausted from the exhaust port 235. At this time, the nitrogen-containing gas is supplied to the wafer 200 from above the wafer 200 (nitrogen-containing gas supply). At this time, the valve 243c may be opened to supply an inert gas into the process chamber 201 via the buffer chamber 237.

At this time, high-frequency (RF) power is applied to the resonance coil 212 from the high-frequency power source 273. As a result, induced plasma having a donut shape in a plan view is excited at height positions corresponding to the upper and lower grounding points and the electrical midpoint of the resonance coil 212 in the plasma generation space 201a. Excitation of the induced plasma activates the nitrogen-containing gas and produces nitriding species. The nitriding species includes at least one of excited N atoms (N*) and ionized N atoms. The symbol * means radicals. The same applies to the following description. Furthermore, when a gas containing hydrogen (H) is used as the nitrogen-containing gas, the nitriding species also includes at least one of excited NH groups (NH*) and ions containing N and H. Furthermore, in this case, reactive species such as excited H atoms (H*) and ionized H atoms may also be generated. These reactive species may also be regarded as part of nitriding species.

Processing conditions in this step are exemplified as follows.
Processing temperature: room temperature to 1000 degrees C., preferably 650 to 900 degrees C.
Processing pressure: 1 to 100 Pa, preferably 3 to 10 Pa
Nitrogen-containing gas supply flow rate: 0.1 to 10 slm, preferably 0.15 to 0.5 slm
Nitrogen-containing gas supply time: 10 to 600 seconds, preferably 20 to 50 seconds
Inert gas supply flow rate: 0 to 10 slm
RF power: 100 to 5000 W, preferably 500 to 3500 W
RF frequency: 800 kHz to 50 MHz

In this specification, the notation of a numerical range such as “650 to 900 degrees C.” means that a lower limit and an upper limit are included in the range. Therefore, for example, “650 to 900 degrees C.” means “650 degrees C. or more and 900 degrees C. or less.” The same applies to other numerical ranges. Further, in this specification, the processing temperature means the temperature of the wafer 200 or the temperature inside the process chamber 201, and the processing pressure means the pressure inside the process chamber 201. In addition, the gas supply flow rate being 0 slm means a case where the gas is not supplied. The same applies to the following description.

By supplying the nitrogen-containing gas excited by plasma to the wafer 200 under the above-described processing conditions, nitriding species are supplied to the inner surface of the trench 301. The inner surface of the trench 301 is nitrided by the supplied nitriding species, and at least a portion of the inner surface is modified into a nitride layer 401 (see FIG. 4B).

For example, the thickness distribution of the nitride layer 401 may be such that the thickness of the nitride layer 401 becomes gradually thinner from the opening 301a of the trench 301 toward the bottom 301b thereof (see FIG. 4B). Further, as an example, the inner surface of the trench 301 near the opening 301a may be modified into a nitride layer 401, and the inner surface near the bottom 301b may be left unmodified into a nitride layer 401 (see FIG. 4B). The reason why the thickness distribution of the nitride layer 401 can be made into such a distribution is that the nitriding species supplied to the inner surface of the trench 301 is consumed by reacting preferentially with the inner surface near the opening 301a, and the amount of nitriding species supplied gradually decreases from the opening 301a toward the bottom 301b. Another reason is that the nitriding species supplied to the inner surface of the trench 301 is deactivated while moving from near the opening 301a to the bottom 301b, and the amount of nitriding species supplied gradually decreases from the opening 301a toward the bottom 301b.

The thickness of the nitride layer 401 at the opening 301a of the trench 301 may be, for example, 1 to 3 nm. The thickness of the nitride layer 401 has the effect of controlling (suppressing) the oxidizing rate in step b as described later, regardless of its magnitude (thinness). However, in order to significantly obtain the effect of controlling (suppressing) the oxidizing rate, the thickness of the nitride layer 401 is preferably 1 nm or more. If the thickness is less than 1 nm, the effect in step b may not be sufficiently obtained.

In this step, the processing pressure is set to a relatively high pressure in order to ensure that the thickness distribution of the nitride layer 401 becomes the above-described distribution. Specifically, when a processing pressure at which the thickness distribution of the nitride layer 401 formed by performing step a becomes uniform over the entire surface of the inner surface of the trench 301 is defined as a “first pressure,” the processing pressure is set to a second pressure higher than the first pressure. By increasing the processing pressure in this manner, the mean free path of the nitriding species inside the process chamber 201 can be shortened, and the probability that the nitriding species will reach the vicinity of the bottom 301b of the trench 301 can be reduced. As a result, it is possible to reliably ensure that the thickness of the nitride layer 401 becomes gradually thinner from the opening 301a of the trench 301 toward the bottom 301b thereof.

After the above-described nitriding process is completed, the valve 253a is closed to stop the supply of the nitrogen-containing gas into the process chamber 201, and also stop the supply of the RF power to the resonance coil 212. Then, the inside of the process chamber 201 is evacuated to remove the gas remaining in the process chamber 201 from the inside of the process chamber 201. At this time, the valve 253c is opened to supply an inert gas into the process chamber 201. The inert gas acts as a purge gas, thereby purging the inside of the process chamber 201 (purging).

As the nitrogen-containing gas, for example, a hydrogen nitride gas such as an ammonia (NH₃) gas, a diazene (N₂H₂) gas, a hydrazine (N₂H₄) gas, an N₃H₈ gas, or the like may be used in addition to the nitrogen (N₂) gas. As the nitrogen-containing gas, one or more of these gases may be used. Further, as the nitrogen-containing gas, a mixed gas of a nitrogen-containing gas and a hydrogen-containing gas, such as a mixed gas of an N₂ gas and a hydrogen (H₂) gas, may be used.

When using a hydrogen-containing gas as the nitrogen-containing gas, as compared to a case where a hydrogen-free gas is used as the nitrogen-containing gas, the nitriding rate for a single component film such as a Si film or the like tends to be higher than the nitriding rate for an oxide film such as a SiO film or the like. Therefore, if a natural oxide film having a non-uniform thickness, i.e., a variation in thickness is formed in the inner surface of the trench 301, it may be difficult to control the thickness distribution of the nitride layer 401 formed on the surface of the wafer 200 due to the influence of the natural oxide film. In this case, by using a H-free gas (e.g., an N₂ gas) as the nitrogen-containing gas, the influence of the natural oxide film can be suppressed, and the controllability of the thickness distribution of the nitride layer 401 formed on the surface of the wafer 200 can be improved, which is preferable.

As the inert gas, for example, an N₂ gas, or a rare gas such as an argon (Ar) gas, a helium (He) gas, a neon (Ne) gas, a xenon (Xe) gas or the like may be used. One or more of these gases may be used as the inert gas. This point also applies to each step described below.

### [Step b: Oxidizing Process]

In step b, an oxygen-containing gas is excited by plasma and supplied to the wafer 200 in the process chamber 201.

Specifically, the valve 253b is opened to allow an oxygen-containing gas to flow into the gas supply pipe 232b. The flow rate of the oxygen-containing gas is adjusted by the MFC 252b. The oxygen-containing gas is supplied into the process chamber 201 via the buffer chamber 237, and is exhausted from the exhaust port 235. At this time, the oxygen-containing gas is supplied to the wafer 200 from above the wafer 200 (oxygen-containing gas supply). At this time, the valve 243c may be opened to supply an inert gas into the process chamber 201 via the buffer chamber 237.

At this time, RF power is applied to the resonance coil 212 from the high-frequency power source 273. As a result, induced plasma is excited similarly in step a. Excitation of the induced plasma activates the oxygen-containing gas and generates oxidizing species. The oxidizing species includes at least one of excited O atoms (O*) and ionized O atoms. Furthermore, when a gas containing H is used as the oxygen-containing gas, the oxidizing species further includes at least one of excited OH groups (OH*) and ions containing O and H. Moreover, in this case, reactive species such as excited H atoms (H*) and ionized H atoms may also be generated. These reactive species may also be considered as part of oxidized species.

Processing conditions in this step are exemplified as follows.
Processing temperature: room temperature to 1000 degrees C., preferably 650 to 900 degrees C.
Processing pressure: 1 to 1000 Pa, preferably 100 to 200 Pa
Oxygen-containing gas supply flow rate: 0.1 to 10 slm, preferably 0.2 to 0.5 slm
Oxygen-containing gas supply time: 10 to 400 seconds, preferably 20 to 50 seconds
   Other processing conditions are the same as those when supplying the nitrogen-containing gas in step a.

The oxidizing species are supplied to the inner surface of trench 301 by supplying the oxygen-containing gas excited by plasma to the wafer 200 under the above-described processing conditions. The supplied oxidizing species oxidizes the inner surface of the trench 301 including the nitride layer 401 to modify it into an oxide layer 402 (see FIG. 4C).

At this time, the nitride layer 401 may be modified into the oxide layer 402 over the entire thickness of the nitride layer 401. Preferably, in the inner surface of the trench 301, the nitride layer 401 and a predetermined region (underlying region where N is not diffused), which is deeper than the nitride layer 401 in the thickness direction of the nitride layer 401 and has not been modified into the nitride layer 401, may be modified into the oxide layer 402. That is, the inner surface that has been modified into the nitride layer 401 by performing step a and the inner surface that has not been modified into the nitride layer 401 even after step a may be modified into the oxide layer 402.

Further, at this time, the thickness distribution of the oxide layer 402 may be such that the thickness becomes gradually thicker from the opening 301a of the trench 301 toward the bottom 301b thereof and preferably becomes thickest at the bottom 301b (see FIG. 4D).

One reason for this is that the rate (oxidizing rate or oxidizing speed) at which silicon nitride (SiN) is modified to silicon oxide (SiO) is lower than the rate (oxidizing rate) at which silicon (Si) is modified to silicon oxide (SiO). In other words, there is selectivity in the oxidizing process in that the oxidizing process on Si alone proceeds more efficiently than the oxidizing process on SiN.

Another reason is that the thickness of the nitride layer 401 formed in step a becomes gradually thinner from the opening 301a of the trench 301 toward the bottom 301b thereof. Preferably, the inner surface of the trench 301 near the bottom 301b is not modified into the nitride layer 401.

For these reasons, the oxidizing rate at the opening 301a of the trench 301 is lower than the oxidizing rate at the bottom 301b of the trench 301. The oxidizing rate in the inner surface of the trench 301 is, for example, lowest at the opening 301a of the trench 301, and gradually increases from the opening 301a toward the bottom 301b.

As a result, for example, in step b, the thickness distribution of the oxide layer 402 can be set such that the thickness of the oxide layer 402 becomes gradually thicker from the opening 301a of the trench 301 toward the bottom 301b and becomes thickest at the bottom 301b. That is, in step a, the thickness distribution of the nitride layer 401 may be adjusted so that in step b, the thickness of the oxide layer 402 becomes gradually thicker from the opening 301a toward the bottom 301b of the trench 301, and/or so that the thickness of the oxide layer 402 becomes thickest at the bottom 301b of the trench 301. In this case, the thickness of the oxide layer 402 at the bottom 301b of the trench 301 may be set to, for example, 5 to 7 nm.

For example, it is also possible to set the thickness distribution of the oxide layer 402 formed in step b so that the thickness of the oxide layer 402 becomes uniform over an entire surface of the inner surface of the trench 301. That is, in step a, the thickness distribution of the nitride layer 401 may be adjusted so that the thickness of the oxide layer 402 formed in step b becomes uniform over the entire surface of the inner surface of the trench 301.

After the above-described oxidizing process is completed, the valve 253b is closed to stop the supply of the oxygen-containing gas into the process chamber 201, and the supply of the RF power to the resonance coil 212 is also stopped.

As the oxygen-containing gas, for example, an oxygen (O₂) gas, an ozone (O₃) gas, an O₂ gas+hydrogen (H₂) gas, a water vapor (H₂O), a hydrogen peroxide (H₂O₂) gas, or the like may be used. As the oxygen-containing gas, one or more of these gases may be used.

In order to increase the oxidizing power of the oxygen-containing gas and reliably oxidize the outermost surface of the trench 301, it is preferable to use a gas further containing hydrogen (H) in addition to oxygen (O), for example, an O₂ gas+H₂ gas, as the oxygen-containing gas. In this case, by increasing the ratio of a H component to an O component contained in the oxygen-containing gas, it is possible to increase the selectivity of the oxidizing process for Si alone, i.e., to increase the ratio (R_{Si}/R_{SiN}) of the oxidizing rate R_{Si} when modifying Si into SiO to the oxidizing rate R_{SiN} when modifying SiN into SiO. This makes it easier to enhance the controllability of the thickness distribution of the oxide layer 402 formed by performing step b, for example, to increase the thickness of the oxide layer 402 at the bottom 301b of the trench 301.

### (After-Purging and Atmospheric Pressure Restoration)

After step b is completed, the inside of the process chamber 201 is evacuated to remove the gas remaining in the process chamber 201 from the inside of the process chamber 201. Then, the gaseous substances remaining in the process chamber 201 are removed from the process chamber 201 using the same processing procedure and processing conditions as those in the above-described purging (after-purging). Thereafter, the atmosphere inside the process chamber 201 is replaced with a purge gas, and the pressure inside the process chamber 201 is returned to the atmospheric pressure (atmospheric pressure restoration).

### (Wafer Unloading)

Subsequently, the susceptor 217 is lowered to a predetermined transfer position, and the wafer 200 is delivered from the susceptor 217 onto the support pins 266. Thereafter, the gate valve 244 is opened, and the processed wafer 200 is unloaded from the process chamber 201 using a transfer robot (not shown). Thus, the substrate processing process according to the present embodiment is completed.

### (3) Effects of the Present Embodiment

According to the present embodiment, one or more of the following effects may be obtained.
(a) By performing step a before step b and setting the thickness distribution of the nitride layer 401 formed in step a to a predetermined distribution, it is possible to set the thickness distribution of the oxide layer 402 formed in step b to a desired distribution.

For example, in step a, the inner surface (especially the side wall surface) near the opening 301a of the trench 301 is modified into the nitride layer 401, and the inner surface near the bottom 301b of the trench 301 is not modified into the nitride layer 401. As a result, the thickness distribution of the oxide layer 402 formed by performing step b can be set such that the thickness of the oxide layer 402 near the bottom 301b becomes thicker than the thickness of the oxide layer 402 near the opening 301a. In addition, in step a, particularly, the inner surface (particularly the side wall surface) of the trench 301 is modified into the nitride layer 401 and the inner surface of the trench 301 near the bottom 301b is not modified into the nitride layer 401, so that the thickness of the nitride layer 401 becomes gradually thinner from the opening 301a toward the bottom 301b. This makes it possible to set the thickness distribution of the oxide layer 402 formed in step b so that the thickness of the oxide layer 402 becomes gradually thicker from the opening 301a of the trench 301 toward the bottom 301b thereof and becomes thickest at the bottom 301b.

For example, in step a, while modifying the entire surface of the inner surface (including the side wall surface and the bottom surface) of the trench 301 into the nitride layer 401, the thickness distribution of the nitride layer 401 is set to a predetermined distribution in which the thickness of the nitride layer 401 becomes gradually thinner from the opening 301a of the trench 301 toward the bottom 301b. This makes it possible to set the thickness distribution of the oxide layer 402 formed in step b so that the thickness of the oxide layer 402 becomes uniform over the entire surface of the inner surface of the trench 301.
(b) In step a, the nitrogen-containing gas can be excited by applying energy with plasma, heat, light, or the like to generate nitriding species, and the nitriding layer 401 can be efficiently formed by supplying the nitriding species to the wafer 200. Furthermore, by taking advantage of the short lifetime of the generated nitriding species, it is possible to enhance the controllability of the thickness distribution of the nitride layer 401 formed in step a, and eventually enhance the controllability of the thickness distribution of the oxide layer 402 formed in step b.
(c) In step b, the oxide layer 402 can be efficiently formed by exciting the nitrogen-containing gas and generating the nitriding species by applying energy with plasma, heat, light, or the like and supplying the nitriding species to the wafer 200.
(d) In steps a and b, the nitride layer 401 and the oxide layer 402 can be formed under relatively low temperature conditions by exciting the nitrogen-containing gas and the oxygen-containing gas using plasma. These make it possible to reduce the thermal history of the wafer 200.
(e) In step a, by using the H-free gas as the nitrogen-containing gas, it is possible to suppress the influence of the natural oxide film having a non-uniform thickness formed in the inner surface of the trench 301, and it is possible to enhance the controllability of the thickness distribution of the nitride layer 401 formed in the inner surface of the trench 301 and, eventually, the controllability of the thickness distribution of the oxide layer 402.
(f) In step b, by using the H-containing gas as the oxygen-containing gas, it is possible to enhance the oxidizing power of the oxygen-containing gas and enhance the efficiency of the oxidizing process.

In this case, by increasing the ratio of the H component (number of H atoms) to the O component (number of O atoms) contained in the oxygen-containing gas, it is possible to enhance the selectivity of the oxidizing process for Si alone to the oxidizing process for SiN (nitride) (to increase the above-mentioned R_{Si}/R_{SiN}). Therefore, for example, when the nitride layer 401 is formed so that the thickness of the nitride layer 401 formed at the bottom 301b of the trench 301 in step a becomes small, or so that the nitride layer 401 is not formed at the bottom 301b of the trench 301, the thickness of the oxide layer 402 formed at the bottom 301b can be adjusted and further selectively increased by increasing the ratio of the H component. Similarly, for example, when the nitride layer 401 is formed in step a so that the thickness of the nitride layer 401 becomes gradually thinner from the opening 301a toward the bottom 301b, the gradient of the thickness of the oxide layer 402, which increases from the opening 301a toward the bottom 301b, can be adjusted to become even thicker by increasing the ratio of the H component.

In this way, by adjusting the ratio of the H component in step b for the trench 301 in which the nitride layer 401 having a predetermined thickness distribution has been formed in step a, the thickness distribution of the oxide layer 402 can be further controlled by adjusting the ratio of the H component in step b. That is, by adjusting the ratio of the H component, it becomes possible to enhance the controllability of the thickness distribution of the oxide layer 402 formed in step b.
(g) In step b, by modifying the nitride layer 401 into the oxide layer 402 throughout the thickness direction of the nitride layer 401, it is possible to ensure that substantially no N remains in the oxide layer 402.

Preferably, in step b, in the inner surface of the trench 301, the nitride layer 401 and the predetermined region (underlying region where N is not diffused), which is deeper than the nitride layer 401 in the thickness direction of the nitride layer 401 and has not been modified into the nitride layer 401, are modified into the oxide layer 402. This makes it possible to more reliably prevent N from remaining in the oxide layer 402.
(h) The above effects can be similarly obtained even when a predetermined substance (gaseous substance, or liquid substance) is arbitrarily selected from the above-mentioned oxygen-containing gas group, nitrogen-containing gas group, and inert gas group.

### (4) Modifications

The substrate processing sequence according to the present embodiment may be modified as shown in the following modifications. These modifications may be combined arbitrarily. Unless otherwise specified, the processing procedure and processing conditions in each step of each modification may be the same as the processing procedure and processing conditions in each step of the substrate processing sequence described above.

### Modification 1

In step a, the processing pressure may be set to a relatively low pressure to reduce the amount of nitriding species generated and to control the thickness distribution of the nitride layer 401, eventually, the thickness distribution of the oxide layer 402. Specifically, the processing pressure is set to a third pressure lower than the “first pressure” mentioned in the description of the above-described embodiment.

Also in this modification, the same effects as those of the above-described embodiment can be obtained. Further, according to this modification, the amount of nitriding species supplied to the wafer 200 can be reduced, most of the nitriding species can be consumed near the opening 301a of the trench 301, and the nitriding species can be prevented from reaching the bottom 301b. As a result, it is easy to set the thickness distribution of the nitride layer 401 such that the thickness of the nitride layer 401 becomes gradually thinner from the opening 301a of the trench 301 toward the bottom 301b thereof.

### Modification 2

In step a, the RF power may be set to be relatively low to reduce the amount of nitriding species generated and to control the thickness distribution of the nitride layer 401 and, eventually, the thickness distribution of the oxide layer 402. Specifically, when the value of the RF power at which the thickness distribution of the nitride layer 401 formed in step a becomes uniform over the entire surface of the inner surface of the trench 301 is defined as a “first power value”′, the RF power value is set to a second power value smaller than the first power value.

Also in this modification, the same effects as those of the above-described embodiment can be obtained. Further, according to this modification, the amount of nitriding species supplied to the wafer 200 can be reduced, most of the nitriding species can be consumed near the opening 301a of the trench 301, and the nitriding species can be prevented from reaching the bottom 301b. As a result, it is easy to set the thickness distribution of the nitride layer 401 such that the thickness of the nitride layer 401 becomes gradually thinner from the opening 301a of the trench 301 toward the bottom 301b thereof.

### Modification 3

In step a, the supply time of the nitrogen-containing gas may be set to be relatively short to reduce the amount of nitriding species supplied to the wafer 200 and to control the thickness distribution of the nitride layer 401 and, eventually, the thickness distribution of the oxide layer 402. Specifically, when the supply time during which the thickness distribution of the nitride layer 401 formed in step a becomes uniform over the entire surface of the inner surface of the trench 301 is defined as a “first supply time”, the supply time is set to a second supply time shorter than the first supply time.

Also in this modification, the same effects as those of the above-described embodiment can be obtained. Further, according to this modification, the amount of nitriding species supplied to the wafer 200 can be reduced, most of the nitriding species can be consumed near the opening 301a of the trench 301, and the nitriding species can be prevented from reaching the bottom 301b. As a result, it is easy to set the thickness distribution of the nitride layer 401 such that the thickness of the nitride layer 401 becomes gradually thinner from the opening 301a of the trench 301 toward the bottom 301b thereof.

### Modification 4

In step a, an ion component such as ionized N atoms or the like may be used as the nitriding species supplied to the wafer 200 to control the thickness distribution of the nitride layer 401 and, eventually, the thickness distribution of the oxide layer 402. Specifically, the impedance changing mechanism 275 is adjusted, and the potential (bias voltage) of the wafer 200 in step a is controlled through the impedance adjustment electrode 217c and the susceptor 217. Thus, the distribution of nitridation by the ion component of the nitriding species drawn into the trench 301 is adjusted so that the thickness distribution of the nitride layer 401 becomes a desired distribution.

Also in this modification, the same effects as those of the above-described embodiment can be obtained. Further, even if the processing pressure is lowered, the ion component such as ionized N atoms or the like has a short mean free path. Therefore, the ion component tends to react with the inner surface of the trench 301 near the opening 301a in a biased manner. As a result, it is easy to set the thickness distribution of the nitride layer 401 such that the thickness of the nitride layer 401 becomes gradually thinner from the opening 301a of the trench 301 toward the bottom 301b thereof.

### Modification 5

In step a, the flow velocity of the nitrogen-containing gas may be set to a relatively large value to control the thickness distribution of the nitride layer 401 and, eventually, the thickness distribution of the oxide layer 402. Specifically, when a flow velocity at which the thickness distribution of the nitride layer 401 formed in step a becomes uniform over the entire surface of the inner surface of the trench 301 is defined as a “first flow velocity”, the flow velocity is set to a second flow velocity higher than the first flow velocity. The flow rate of the nitrogen-containing gas is adjusted, for example, by controlling the flow rate of the nitrogen-containing gas supplied into the process chamber 201.

Also in this modification, the same effects as those of the above-described embodiment can be obtained. Further, according to this modification, by increasing the flow velocity of the nitriding species, the flow velocity of the nitriding species near the bottom 301b can be set to be relatively smaller than the flow velocity of the nitriding species near the opening 301a, and the inner surface near the opening 301a of the trench 301 can be preferentially nitrided. As a result, it is easy to set the thickness distribution of the nitride layer 401 such that the thickness of the nitride layer 401 becomes gradually thinner from the opening 301a of the trench 301 toward the bottom 301b thereof.

### OTHER EMBODIMENTS

The embodiment of the present disclosure has been described above. However, the embodiment of the present disclosure is not limited to the above-described one, and may be modified in various forms without departing from the spirit thereof.

In the above-described embodiment, there has been described the example in which a portion of the inner surface of the trench 301 is modified into the nitride layer 401 in step a. However, the present disclosure is not limited thereto. For example, the entire surface of the inner surface of the trench 301 may be modified into the nitride layer 401. Also in this case, the same effects as in the above-described embodiment can be obtained.

In the above-described embodiment, there has been described the example in which the nitrogen-containing gas and the oxygen-containing gas are excited by plasma. However, the present disclosure is not limited thereto. For example, the nitrogen-containing gas and the oxygen-containing gas may be excited by heat or light. Also in this case, the same effects as in the above-described embodiment can be obtained. Furthermore, it is possible to avoid plasma damage to the wafer 200 and the like.

In the above-described embodiment, the trench 301 has been described as an example of the recessed structure. However, the present disclosure is not limited thereto. For example, a hole may be formed on the surface of the wafer 200 as the recessed structure. Further, the recessed structure may be formed so that the width thereof becomes larger from the opening 301a toward the bottom 301b (the distance between the opposing inner surfaces gradually increases). Further, the recessed structure may be formed so that the width thereof becomes smaller from the opening 301a toward the bottom 301b (the distance between the opposing inner surfaces gradually decreases). In these cases as well, the same effects as those of the above-described embodiment can be obtained.

Although not described in the above-described embodiment, in the present disclosure, a wafer 200 in which a trench 301 having an aspect ratio of 10 or more or 20 or more is formed may be used. According to the present disclosure, even when using the wafer 200 having such a high aspect ratio, the same effects as those of the above-described embodiment can be obtained.

In the above-described embodiment, there has been described the example in which the inner surface of the trench 301 is made of a Si layer consisting of Si alone. However, the present disclosure is not limited thereto. For example, the inner surface of the trench 301 may be made of a Si-containing substance (Si compound) such as silicon carbide (SiC) or silicon germanium (SiGe). Further, the inner surface of the trench 301 may be made of a metal containing aluminum (Al), titanium (Ti), hafnium (Hf) or zirconium (Zr), or a compound thereof. However, the inner surface of the trench 301 is preferably made of substances other than these oxides and nitrides.

In the above-described embodiment, there has been described the example in which the nitriding process (step a) and the oxidizing process (step b) are performed continuously in a single process chamber (i.e., the process chamber 201). However, the present disclosure is not limited thereto. For example, after performing the nitriding process (step a) on a substrate, the substrate may be transferred from the process chamber where the nitriding process was performed to a transfer chamber that is not opened to the atmosphere. Thereafter, the substrate may be loaded into another process chamber to perform the oxidizing process (step b).

In the above-described embodiment, there has been described the example in which the substrate processing process is performed using, for example, a single-substrate type substrate processing apparatus that processes one or several substrates at a time. The present disclosure is not limited to the above-described embodiment, but may also be suitably applied to a case of using a batch-type substrate processing apparatus that processes a plurality of substrates at a time.

Even when using these substrate processing apparatuses, each process can be performed under the same sequence and processing conditions as in the above-described embodiment and modifications, and the same effects as those of the above-described embodiment and modifications can be obtained.

According to the present disclosure in some embodiments, it is possible to selectively form the film on the surface of the desired base by selectively forming the adsorption-inhibiting layer on the surface of the specific base.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising: (a) nitriding an inner surface of a recessed structure formed on the substrate to modify at least a portion of the inner surface into a nitride layer; and
(b) oxidizing the inner surface including the nitride layer to modify the inner surface into an oxide layer,
wherein (a) includes setting a thickness distribution of the nitride layer in the inner surface such that, in (b), a thickness distribution of the oxide layer in the inner surface becomes a desired distribution.

2. The method of claim 1, wherein (a) includes:
exciting a nitrogen-containing gas to generate a nitriding species; and
supplying the nitriding species to the substrate.

3. The method of claim 2, wherein (a) further includes exciting the nitrogen-containing gas by plasma or heat.

4. The method of claim 2, wherein the nitrogen-containing gas is a hydrogen-free gas.

5. The method of claim 1, wherein (a) includes setting the thickness distribution of the nitride layer such that a thickness of the nitride layer becomes gradually thinner from an opening of the recessed structure to a bottom of the recessed structure.

6. The method of claim 1, wherein (a) includes modifying an entire surface of the inner surface to the nitride layer.

7. The method of claim 1, wherein (a) includes modifying the inner surface near an opening of the recessed structure to the nitride layer, and not modifying the inner surface near a bottom of the recessed structure to the nitride layer.

8. The method of claim 1, wherein the inner surface nitrided in (a) contains silicon.

9. The method of claim 1, wherein (b) includes exciting an oxygen-containing gas to generate an oxidizing species; and
supplying the oxidizing species to the substrate.

10. The method of claim 9, wherein (b) further includes exciting the oxygen-containing gas by plasma or heat.

11. The method of claim 9, wherein the oxygen-containing gas is a gas containing hydrogen.

12. The method of claim 11, wherein (b) further includes controlling the thickness distribution of the oxide layer by adjusting a ratio of hydrogen to oxygen contained in the oxygen-containing gas.

13. The method of claim 1, wherein (b) includes modifying the nitride layer to the oxide layer over an entirety of a thickness direction of the nitride layer.

14. The method of claim 1, wherein (b) includes setting the thickness distribution of the oxide layer such that a thickness of the oxide layer becomes gradually thicker from an opening of the recessed structure toward a bottom of the recessed structure and becomes thickest at the bottom of the recessed structure.

15. The method of claim 14, wherein in (a), the thickness distribution of the nitride layer is set such that, in (b), the thickness of the oxide layer becomes gradually thicker from the opening of the recessed structure toward the bottom of the recessed structure and becomes thickest at the bottom of the recessed structure.

16. The method of claim 1, wherein (b) includes setting a thickness distribution of the oxide layer such that a thickness of the oxide layer becomes uniform over an entire surface of the inner surface.

17. The method of claim 16, wherein (a) includes setting a thickness distribution of the nitride layer such that, in (b), the thickness of the oxide layer becomes uniform over the entire surface of the inner surface.

18. A method of manufacturing a semiconductor device comprising the method of claim 1.

19. A substrate processing apparatus, comprising:
a process chamber configured to accommodate a substrate;
a nitrogen-containing gas supplier configured to supply a nitrogen-containing gas into the process chamber;
an oxygen-containing gas supplier configured to supply an oxygen-containing gas into the process chamber;
an excitation part configured to excite the gases supplied from the nitrogen-containing gas supplier and the oxygen-containing gas supplier; and
a controller configured to be capable of controlling the nitrogen-containing gas supplier, the oxygen-containing gas supplier, and the excitation part to perform in the process chamber:
(a) supplying a nitriding species generated by exciting the nitrogen-containing gas to the substrate having a recessed structure formed on a surface of the substrate, nitriding an inner surface of the recessed structure, and modifying at least a portion of the inner surface into a nitride layer; and
(b) supplying an oxidizing species generated by exciting the oxygen-containing gas to the substrate, oxidizing the inner surface including the nitride layer, and modifying the inner surface into an oxide layer,
wherein (a) includes setting a thickness distribution of the nitride layer in the inner surface such that, in (b), a thickness distribution of the oxide layer in the inner surface becomes a desired distribution.

20. A non-transitory computer-readable recording medium storing a program that causes, by a computer, a substrate processing apparatus to perform a process in a process chamber of the substrate processing apparatus, the process comprising:
(a) nitriding an inner surface of a recessed structure formed on a substrate to modify at least a portion of the inner surface into a nitride layer; and
(b) oxidizing the inner surface including the nitride layer to modify the inner surface into an oxide layer,
wherein (a) includes setting a thickness distribution of the nitride layer in the inner surface such that, in (b), a thickness distribution of the oxide layer in the inner surface becomes a desired distribution.
